(19) United States
(12) Patent Application Publication
(10) Pub. No.: US 2012/0281371 A1
(43) Pub. Date: Nov. 8, 2012

(54) CONTROLLER FOR HVAC WITH INSTRUCTION SHEET SLOT

(75) Inventors: Glenn A. Moore, Geneva, IL (US); Ernest E. Soderlund, Hampshire, IL (US); Daniel Poplawski, Oswego, IL (US)

(73) Assignee: Braeburn Systems, LLC., Montgomery, IL (US)

(21) Appl. No.: 13/102,820

(22) Filed: May 6, 2011

(51) Int. Cl. H05K 5/02; H05K 5/00

(52) U.S. Cl. 361/752; 361/809; 361/679.01

(57) ABSTRACT

The present invention provides for a controller for an HVAC system comprising a controller assembly including a main housing having a mounting plate for mounting the controller assembly to a building wall, the mounting plate having at least one side and a back surface for facing the building wall when mounted thereto, a sheet receiving slot disposed in the back surface and the slot having a side opening in the side of the mounting plate, the slot configured for receiving an instruction sheet through the side opening in order to allow insertion and removal of the instruction from the slot.

The present invention pertains to a controller for HVAC system such as a thermostat having a slot for receiving an instruction sheet.

### BACKGROUND

Current controllers such as thermostats may provide for intuitive operation and programming. The thermostats include user interfaces that enhance programming and operation. For example, LCD screens with sophisticated displays help to guide a user in the programming and functioning of the controller. Despite these improvements users still may favor the use of a printed instruction guide, owner's manual or other documentation for the controller; in order to assist in the programming and operation.

The use of instruction guide can only be accomplished when the user can easily locate such documentation. Since many controllers are installed by third parties, who may fail to leave the documentation with the owner, or such documentation may become misplaced; it is useful to provide an instruction sheet or documentation with the controller unit itself. For example, some controllers include a flip-flop door, upon which instructions are printed. Other controllers are known to have cavities within the controller for locating an instruction sheet. However, such arrangement require some disassembly of the controller or removal of the controller from the wall to which it is mounted in order to access the instruction sheet. The present invention overcomes the disadvantages of such previous systems.

### SUMMARY

The present invention provides for a controller for an HVAC system comprising controller assembly including a main housing having a mounting plate for mounting the controller assembly to a building wall, the mounting plate having at least one side and a back surface for facing the building wall when mounted thereto, a sheet receiving slot disposed in the back surface and the slot having a side opening in the side of the mounting plate, the slot configured for receiving an instruction sheet through the side opening in order to allow insertion and removal of the instruction from the slot.

In an embodiment, a major portion of a first side of the slot may be formed completely within the back surface of the mounting plate. In an embodiment, the first side of the slot may be defined by three interior walls of the mounting plate and a major back wall of the slot formed by a vertical interior wall of the mounting plate. In an embodiment, the controller comprises a second side of the slot opposite the first side of the slot and the second side of the slot may be provided by the building wall when the mounting plate is secured to the building wall and the building wall helps to secure the instruction sheet within the slot.

In an embodiment, the side opening of the slot may be located along a top side of the controlled assembly. In an embodiment, the slot may be formed by interior wall so the mounting plate surrounding the slot of three sides. In an embodiment, the slot may include the side opening at the side of the mounting plate and the slot may also have a back opening in a plane being parallel to the plane of the back surface of the mounting plate. In an embodiment, the three interior walls of the slot having a restraining member extending from each interior wall and protruding into the back opening of the slot, in order to restrain the sheet and prevent the sheet from falling through the back opening. In an embodiment, the restraining members may be configured to sufficiently restrain the sheet while the mounting plate is being removed from a shipping package and mounted to the building wall. In an embodiment, the restraining members may extend into the back opening at least one-eight of an inch.

In an embodiment, the slot may be open on a back side that is coplanar with the back surface of the mounting plate so that upon mounting of the mounting plate to the building wall, it will provide a back wall of the slot in order that an instruction sheet placed within the slot cannot fall out through the back side opening. In an embodiment, the back surface may provide a frame surrounding the back side opening and the frame may be generally flat, so that the frame may abut the building wall in a flush orientation in order to prevent the sheet from falling from the slot.

In an embodiment, the mounting plate and the main housing may be integrally formed together. In an embodiment, the mounting plate may be removably mounted to the main housing, so that the mounting plate may be first mounted to the building wall and thereafter the main housing may be mounted to the mounting plate. In an embodiment, the mounting plate includes detents along a front surface so that the main housing may be snap-fit thereto. In an embodiment, the instruction sheet may include a tab extending from an edge so that, when the sheet is fully inserted within the slot, the tab will protrude out the slot and beyond the side of the mounting plate and a user may grasp the tab to remove the sheet from the slot. In an embodiment, the instruction sheet tab extends from the top side of the controller assembly.

In an embodiment, the instruction sheet may comprise multiple pages and the sheet may be folded in an accordion style. In an embodiment, the slot is configured to allow for multiple instruction sheets to reside therein. In an embodiment, the controller assembly may include a printed circuit board having electrical components and the slot configured to prevent the sheet from abutting the electrical components when the sheet is located within the slot. In an embodiment, the sheet may be constructed to reserve an area for written identification of the installing service organization.

Further the invention may provide a controller for an HVAC system comprising a controller assembly including a back surface for facing a building wall when mounted thereto, the back surface having a recessed area forming a sheet receiving slot, the slot having a first open side for receiving an instruction sheet therethrough. The first open side may be a top side of the controller. The slot may include restraining members for restraining the sheet within the slot. The recessed area may be located at one side of the mounting plate so that the first open side is coplanar with the one side of the mounting plate. The main housing may have a mounting plate and the sheet receiving slot may be formed in the mounting plate.

### BRIEF DESCRIPTION OF THE DRAWINGS

The invention may be more completely understood in consideration of the following description of various embodiments of the invention in connection with the accompanying drawings, in which:

FIG. 1 is a perspective view of the front of a controller of the present invention.

FIG. 2 is a perspective view of the back side of a controller of the present invention having an instruction sheet fully inserted in a slot of the controller;

FIG. 3 is a perspective view of the back side of a controller of the present invention depicting an instruction sheet removed from the slot;

FIG. 4 is an enlarged view of the slot of the controller depicted in FIGS. 2 and 3.

While the invention is amendable to various modifications and alternate forms, specifics thereof have been shown by way of example in the drawings and will be described in detail. It should be understood, however, that the intention is not to limit the invention to the particular embodiments described. The intention is to cover all modifications, equivalents, and alternatives falling within the spirit and scope of the invention.

### DETAILED DESCRIPTION

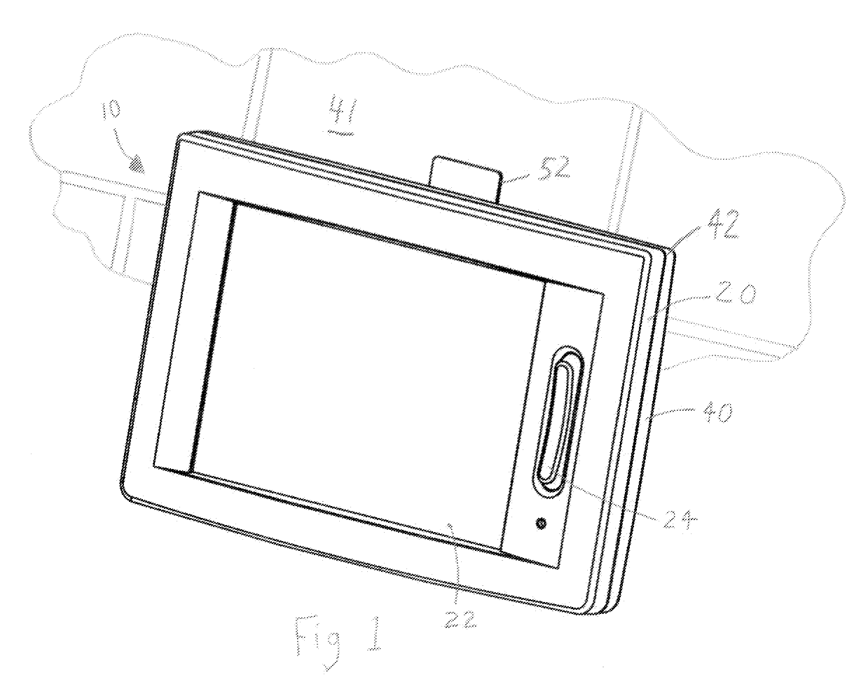

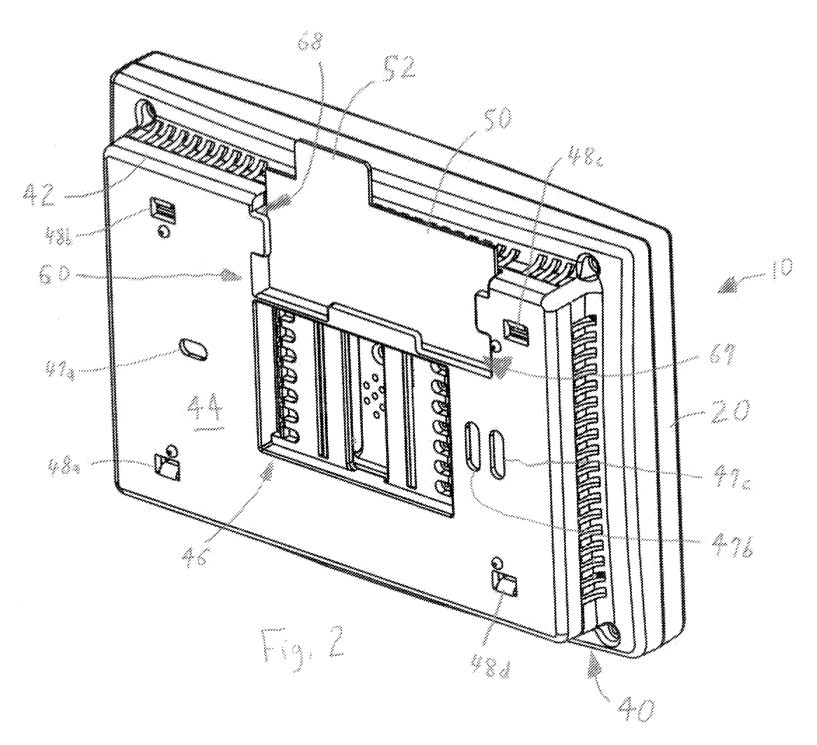

The present invention is described with respects to FIGS. 1-4. A controlled 10 such as a thermostat includes a main housing 20 which forms the front side of the controlled 10. The main housing 20 also includes an LCD display screen 22 and a mechanical button(s), such as button 24. Other types of displays of displays may be included such a dot matrix LED. The thermostat may be operated by use of the LCD display screen 22 and the mechanical button 24 by means such as disclosed in application Ser. No. 12/982,959, which is incorporated herein by reference. The main housing 20 is mounted to a rear plate 40 by well known means such as fasteners or snap-fit detents (not shown). As is well known, with other controllers of this type the mounting plate 40 may be mounted to a building wall 41 as the first step in the assembly. After the mounting plate 40 is securely fastened to the building wall 41, the main housing 20 may be snap-fit to the mounting plate 40. The mounting plate 40 includes four sides including a top side 42 and a back surface 44. The back surface 44 of the mounting plate 40 includes multiple features formed therein including an opening 46, fastener apertures 47a, b, c for commonly available mounting points on building wall 41 and snap members 48a, b, c, d (FIG. 2) to retain mounting plate 40 to main housing 20. Opening 46 provides for wiring access to the internal connections of the controller.

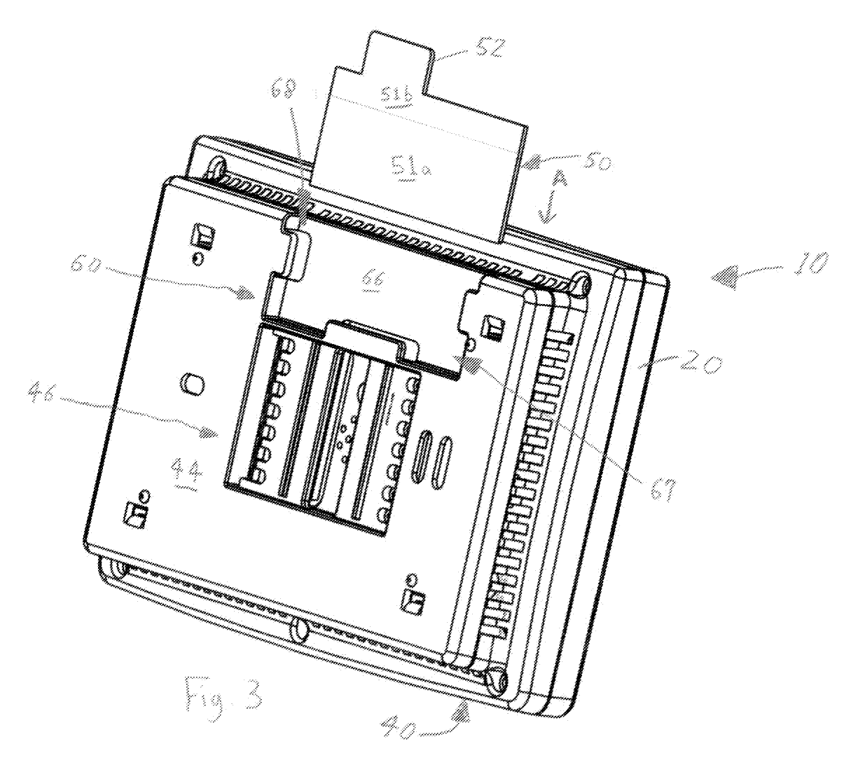

An instruction sheet 50 that includes a tab 52 is inserted in slot 60 formed in the back surface 44 of the mounting plate 40. In an embodiment, the instruction sheet 50 may be a single sheet formed of rigid laminated card stock or plastic material. In a further alternate embodiment, multiple instruction sheets may be provided. For example, a first instruction sheet in the English language and a second or third sheet in other foreign languages. In an alternative embodiment, the instruction sheet may include English on a portion of the sheet and a foreign language on a further portion of the same sheet. In an embodiment, the instruction sheets will be printed with text providing basic operations such as setting heat and cool of programming a 5-2 or 7-day commercial or residential programming. In an embodiment, the instruction sheet 50 may be folded in an accordion style in order to provide a large amount of material in a small space. As show in FIG. 1, the tab 52 protrudes from a top side 42 of the mounting plate 40 so that the tab 52 is visible from the front side of the controller 10 (FIG. 1) and a user may grab the tab with their fingers in order to easily remove the instruction sheet 50 from the slot 60 when the controller 10 is mounted to a building wall 41. In an embodiment, the instruction sheet may be printed with an area reserved for the installing service organization to add written contact information that identifies the installing service organization. For example, as shown in FIG. 3, the instruction sheet 50 includes a first content area 51a for providing written instructions pertaining to the operation of the controller and a second content area 51b for identification of the installing service organization. In an embodiment, both sides of the sheet 50 may have writing and both sides may have a first content area 51a and a second content area 51b.

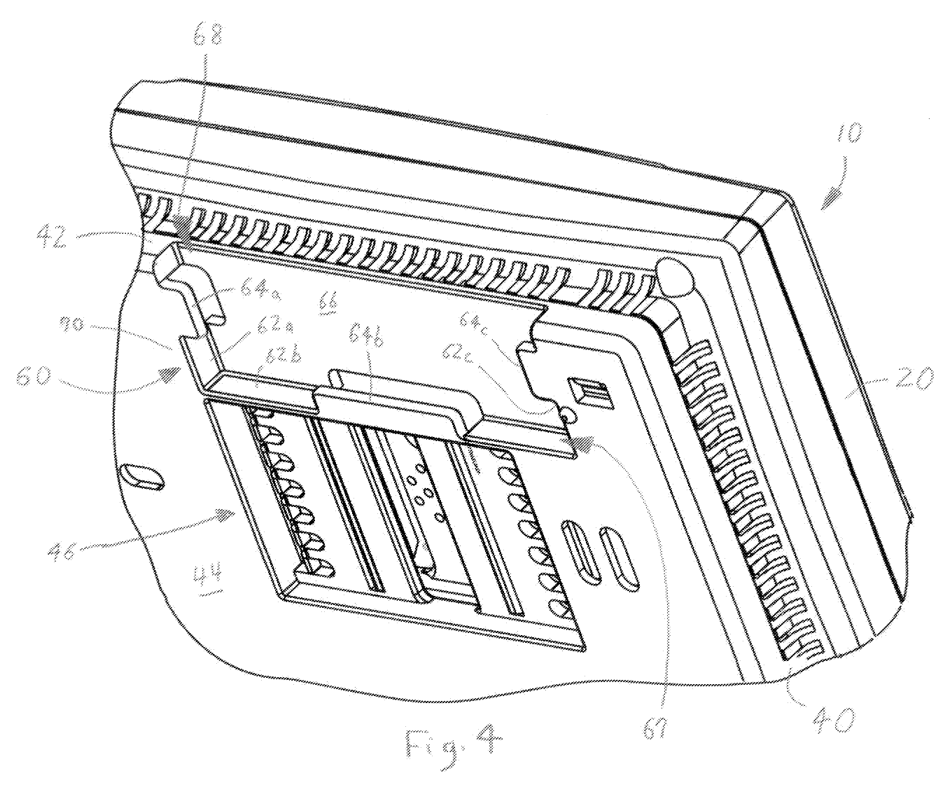

The slot 60 is formed in the back surface 44 of the mounting plate 40. In an embodiment, the slot 60 is generally rectangular shaped and is formed by a recessed area in the back surface 44 by inter walls 62a, b, c. The interior walls 62a, b, c surround a back wall 66 formed in the mounting plate 40 (FIG. 4). Opposite the back wall 66 is a back opening 67 formed by the interior walls 62a, b, c that exposes the interior of the slot 60. The back opening 67 is generally coplanar with the back surface 44 of the mounting plate 40. Restraining members 64a, b, c extend into the back opening 67 from each of the interior walls 62. The restraining members 64a, b, c extend into the back opening 67 in order to restrain the instruction sheet 50 from falling through the back opening 67 (FIG. 2). The restraining members 64a, b, c are generally shaped as merlons, however, alternate shaped members may also provide for the restraining function. Further, a single retaining member may be provided that extends around the entire perimeter of the slot 60 in order to retain the instruction sheet therein.

The slot 60 is formed in the back surface 44 so that a side opening 68 is formed in the top side 42 of the mounting plate 40. The side opening 68 allows for the instruction sheet 50 to be inserted into the slot 60 through the top side of the controller 10. FIG. 3 depicts the instruction sheet 50 being inserted into the slot 60 by moving the instruction sheet 50 downward in direction of arrow A.

The slot 60 includes a frame area 62 surrounding the perimeter of the slot 60. In an embodiment, when the mounting plate 40 is mounted to a building wall 41 the frame area 70 will mount flush with the wall. In that arrangement, the interior walls 62a, b, c, and back surface 44 provide a first side of the slot. The building wall 41, to which mounting plate 40 is attached, forms a second side of the slot 60 so that the building wall 41 helps to secure the instruction sheet 50 within the slot 60. The building wall 41 acts to enclose the back opening 67 formed by the slot 60.

It may be understood that when the controller 10 is fully mounted to the building wall 41 an instruction sheet 50 may be stored in the slot 60 and upon grabbing of the tab 52 by user's fingers the instruction sheet 50 may be easily withdrawn through the side opening 68 of the slot 60, so that the instruction sheet 50 may be viewed by the user. Returning the instruction sheet 50 back to the slot 60 is an easy operation; in that the user pushes instruction sheet 50 all the way back toward the building wall 41 and slides the instruction sheet 50 down into the slot 60 through the side opening 68 (FIG. 3).

When the mounting plate 40 is mounted to a building wall 41 the restraining members 64a, b, c act as a primary means of restraining the instruction sheet 50 within the slot 60; and the building wall 41 acts as a secondary means to restrain the instruction sheet 50 within the slot 60. When controller 10 is removed from mounting plate 40 for service, replacement or other purposes, mounting plate 40 and restraining members 64a, b, c will act to retain the instruction sheet 50 within slot 60 during service of the controller.

The restraining members 64a, b, c are thinly constructed so that the card may be slid easily within the slot 60. In an embodiment, each of the restraining members has a height of 0.100 and a thickness of at least 0.110 for offset of the instruction sheet 50 from the building wall 41. In other words, to allow a user to more easily grab the tab 52 of the instruction sheet 50, it is necessary to space the instruction sheet 50 from the building wall 41 to provide room for a user's fingers to grasp both sides of the tab 52. Having restraining members with a thickness of at least 0.050 disposed between the instruction sheet 50 and building wall 41 provides an off-set from the building wall 41 when the instruction sheet is residing in the slot 60. In an embodiment, the dimensions of the slot are approximately 1 inch by 1.7 inches by 0.125 inches. When the instruction sheet 50 is placed within the slot 60 the walls 62a, b, c, 66 protect the instruction sheet 50 from the interior electronic components of the controller 10.

While various concepts have been described in detail, it would be appreciated by those skilled in the art that various modifications and alternatives to those concepts could be developed in light of the overall teachings of the disclosure. Therefore, a person skilled in the art, applying ordinary skill, will be able to practice the invention set forth in the claims without undue experimentation. It will additionally be appreciated that the particular concepts exposed herein are meant to be illustrative only and not limiting to the scope of the invention, which is to be given the full breath of the appended claims and any equivalents thereof.

What is claimed:

1. A controller for an HVAC system comprising:
a controller assembly including a main housing having a mounting plate for mounting the controller assembly to a building wall;
the mounting plate having at least one side and a back surface for facing the building wall when mounted thereto:
a sheet receiving slot disposed in the back surface; and
the slot having a side opening in the side of the mounting plate, the slot configured for receiving an instruction sheet through the side opening in order to allow for insertion and removal of the instruction sheet from the slot.

2. The controller of claim 1, wherein a major portion of a first side of the slot is formed completely within the back surface of the mounting plate.

3. The controller of claim 2, wherein the first side of the slot is defined by three interior walls of the mounting plate and a major back wall of the slot formed by a vertical interior wall of the mounting plate.

4. The controller of claim 3, further comprising a second side of the slot opposite the first side of the slot and the second side of the slot provided by the building wall when the mounting plate is secured to the building wall wherein the building wall helps to secure the instruction sheet within the slot.

5. The controller of claim 1, wherein the side opening of the slot is located along a top side of the controller assembly.

6. The controller of claim 1, wherein the slot is formed by interior walls of the mounting plate surrounding the slot on three sides.

7. The controller of claim 6, wherein the slot includes the side opening at the side of the mounting plate and the slot also having a back opening in a plane being parallel to the plane of the hack surface of the mounting plate.

8. The controller of claim 7, wherein the three interior walls of the mounting plate having a restraining member extending from each interior wall and protruding into the back opening of the slot in order restrain the sheet and prevent the sheet from falling through the back opening.

9. The controller of claim 8, wherein the restraining members are configured to sufficiently restrain the street while the controller is being removed from the building wall when the controller is being serviced.

10. The controller of claim 1, wherein the slot is open on a back side that is coplanar with the back surface of the mounting plate so that upon mounting of the mounting plate to the building wall, it will provide a back wall of the slot in order that an instruction sheet placed within the slot cannot fall our through the back side opening.

11. The controller of claim 10, wherein the back surface provides a frame surrounding the back side opening and the frame is generally flat, so that the frame may abut the building wall in a flush orientation in order to prevent the sheet from falling from the slot.

12. The controller of claim 1, wherein the mounting plate and the main housing are integrally formed together.

13. The controller of claim 1, wherein the mounting plate is removably mounted to the main housing, so that the mounting plate may first be mounted to the building wall and thereafter the main housing may be mounted to the mounting plate.

14. The controller of claim 1, wherein the mounting plate includes detents along a front surface so that the main housing may be snap-fit thereto.

15. The controller of claim 1, wherein the instruction sheet includes a tab extending from an edge so that when the sheet is fully inserted within the slot the tab will protrude out of the slot and beyond the side of the mounting plate and a user may grasp the tab to remove the sheet from the slot.

16. The controller of claim 15, wherein the instruction sheet tab extends from the top side of the controller assembly.

17. The controller of claim 1, wherein the instruction sheet comprises multiple pages and the sheet is folded in an accordion style.

18. The controller of claim 1, wherein the slot is configured to allow for multiple instruction sheets to reside therein.

19. The controller of claim 1, wherein the controller assembly includes a printed circuit board having electrical components and the slot configured to prevent the sheet from abutting the electrical components when the sheet is located within the slot.

20. The controller of claim 1, wherein the instruction sheet includes a first content area for providing written instructions pertaining to the operation of the controller and a second content area for identification of the installing service organization.

21. A controller for an HVAC system comprising:
a controller assembly including a back surface for facing a building wall when mounted thereto;
the back surface having a recessed area forming a sheet receiving slot, the slot having a first open side for receiving an instruction sheet therethrough.

22. The controller of claim 21, wherein the first open side is at a top side of the controller.

23. The controller of 21, wherein the slot includes restraining members for restraining the sheet within the slot.

24. The controller of claim 21, wherein the recessed area is located at one side of the mounting plate so that the first open side is coplanar with the one side of the mounting plate.

25. The controller of claim 21, further including a main housing having a mounting plate and the sheet receiving slot formed in the mounting plate.

26. The controller of claim 21, further including an off-set member disposed in the slot for spacing the instruction sheet from the building wall when the instruction sheet is received in the slot.

27. The controller of claim 21, wherein the instruction sheet includes a first content area for providing written instructions pertaining to the operation of the controller and a second content area for identification of the installing service organization.
